(19) United States
(12) Patent Application Publication
(10) Pub. No.: US 2008/0153236 A1
(43) Pub. Date: Jun. 26, 2008

(54) FLASH MEMORY DEVICES AND METHODS FOR FABRICATING THE SAME

(76) Inventors: Ning Cheng, San Jose, CA (US); Kuo-Tung Chang, Saratoga, CA (US); Hiroyuki Kinoshita, San Jose, CA (US); Minh-Van Ngo, Fremont, CA (US); Fred Cheung, San Jose, CA (US); Alexander Nickel, Santa Clara, CA (US)

Correspondence Address: INGRASSIA FISHER & LORENZ, P.C., 7010 E. COCHISE ROAD, SCOTTSDALE, AZ, 85253, US

(21) Appl. No.: 11/615,425

(22) Filed: Dec. 22, 2006

(51) Int. Cl. H01L 21/336

(52) U.S. Cl. 438/287; 257/E21.423

(57) ABSTRACT

Flash memory devices and methods for fabricating the same are provided. A method for fabricating a memory device comprises the steps of fabricating a first gate stack and a second gate stack overlying a P-type silicon substrate and implanting an impurity dopant into the substrate substantially between the first gate stack and the second gate stack to form an impurity-doped region of the substrate. A channel region underlies the first gate stack adjacent to the impurity-doped region. An intrinsically tensile-stressed insulating member is formed between the first and the second gate stacks and overlying the impurity-doped region. The tensile-stressed insulating member causes a uniaxial lateral tensile stress to be transmitted to the first channel region. A word line is formed overlying the intrinsically tensile-stressed insulating member and in electrical contact with the first gate stack and the second gate stack.

### FIELD OF THE INVENTION

The present invention generally relates to flash memory devices and methods for fabricating flash memory devices, and more particularly relates to memory devices with increased channel mobility and methods for fabricating the same.

### BACKGROUND OF THE INVENTION

A type of commercially available flash memory product is a MirrorBit® memory device available from Spansion, LLC, located in Sunnyvale, Calif. A MirrorBit cell effectively doubles the intrinsic density of a flash memory array by storing two physically distinct bits on opposite sides of a memory cell. Each bit within a cell can be programmed with a binary unit of data (either a logic one or zero) that is mapped directly to the memory array.

An exemplary MirrorBit® memory device 10, illustrated in FIG. 1, includes a P-type semiconductor substrate 12 within which are formed spaced-apart source/drain regions 14, 16 respectively (both typically having N-type conductivity), otherwise known as bit lines. A charge trapping layer or stack 18 is disposed on the top surface of the substrate between the bit lines. The charge trapping stack 18 typically comprises, for example, a charge trapping layer, often a silicon nitride layer 20, disposed between a first or bottom silicon dioxide layer (commonly referred to as a tunnel oxide layer) 22 and a second or top silicon dioxide layer 24. A gate electrode 26, which typically comprises an N or N+ polycrystalline silicon layer, is formed over the charge trapping stack to form a first storage element or bit 28 and a second storage element or bit 30 of memory cells 32 and 34. The charge trapping layer 20 of first storage bit 28 and the charge trapping layer 20 of second storage bit 30 of each memory cell 32 and 34 can be integral, as illustrated in FIG. 1, or can be separated by an isolation element, which typically is an oxide often referred to as a gate oxide. A layer 36 of insulating material, such as a silicon oxide or a silicon nitride, is disposed between the memory cells 32 and 34 to electrically isolate them. A conductive word line 38 is disposed overlying layer 36 and in electrical contact with memory cells 32 and 34.

A dual bit memory cell 34 is programmed utilizing a hot electron injection technique. More specifically, programming of the first bit 28 of memory cell 34 comprises injecting electrons into the charge trapping layer 20 while applying a bias between bit lines 14 and 16 and applying a high voltage to the control gate 26. In an exemplary embodiment, this may be accomplished by grounding bit line 16 and applying approximately 5 V to bit line 14 and approximately 10 V to the control gate 26. The voltage on the control gate 26 inverts a channel region 36 while the bias accelerates electrons from bit line 14 into the channel region 36 towards bit line 16. The 4.5 eV to 5 eV kinetic energy gain of the electrons is more than sufficient to surmount the 3.1 eV to 3.5 eV energy barrier at channel region 36/tunnel oxide layer 22 interface and, while the electrons are accelerated towards source/drain region 16, the field caused by the high voltage on control gate 26 redirects the electrons towards the charge trapping layer of first bit 28. Those electrons that cross the interface into the charge trapping layer remain trapped for later reading.

Similarly, programming the second bit 30 by hot electron injection into the charge trapping layer 20 comprises applying a bias between bit lines 16 and 14 while applying a high voltage to the control gate 26. This may be accomplished by grounding bit line 14 and applying approximately 5V to bit line 16 and approximately 10 V to the control gate 26. The voltage on the control gate 26 inverts the channel region 36 while the bias accelerates electrons from bit line 16 into the channel region 36 towards bit line 14. The field caused by the high voltage on control gate 26 redirects the electrons towards the charge trapping layer of second bit 30. Those electrons that cross the interface into charge trapping layer 20 of second bit 30 remain trapped for later reading.

With advances in semiconductor process technology, the trend is toward smaller semiconductor devices, including memory devices, that have increased performance and capabilities. As electronic devices approach the 45 nm size and even smaller sizes, devices with increased operating speed and increased operating range are desired. However, such advances should come without adding significant complexity to the manufacture of the devices and without adding significant cost to the manufacture of the devices.

Accordingly, it is desirable to provide a flash memory device with increased operating speed that can be scaled in size. In addition, it is desirable to provide a flash memory device with increased operating speed that can be fabricated without significant additional complexity and/or cost. It also is desirable to provide methods for fabricating such flash memory devices. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

In accordance with an exemplary embodiment of the invention, a method for fabricating a memory device comprises the steps of fabricating a first gate stack and a second gate stack overlying a P-type silicon substrate and implanting an impurity dopant into the substrate substantially between the first gate stack and the second gate stack to form an impurity-doped region of the substrate. A first channel region underlies the first gate stack adjacent to the impurity-doped region. An intrinsically tensile-stressed insulating member is formed between the first and the second gate stacks and overlying the impurity-doped region. The tensile-stressed insulating member causes a uniaxial lateral tensile stress to be transmitted to the first channel region. A word line is formed overlying the intrinsically tensile-stressed insulating member and in electrical contact with the first gate stack and the second gate stack.

In accordance with another exemplary embodiment of the invention, a method for enhancing the speed of a dual bit memory device comprises the steps of forming a charge trapping layer overlying a P-type silicon substrate, depositing a control gate material layer overlying the charge trapping layer, and etching the control gate material layer and the charge trapping layer to form a first gate stack and a second gate stack. An impurity-doped region is formed in the substrate substantially between the first gate stack and the second gate stack. An intrinsically tensile-stressed insulating member is fabricated between the first and the second gate stacks and overlying the impurity-doped region. The intrinsically tensile-stressed insulating member has an intrinsic tensile stress of at least about 0.5 GPa.

In accordance with a further exemplary embodiment of the present invention, a memory device comprises a P-type silicon substrate, a dielectric-charge trapping-dielectric stack disposed on the substrate, and an N⁺-doped impurity region disposed within the substrate. A channel region is disposed within the substrate underlying the dielectric-charge trapping-dielectric stack. An intrinsically tensile-stressed insulating member is disposed overlying the N⁺-doped impurity region. The tensile-stressed insulating member is configured to cause a uniaxial lateral tensile stress to be transmitted to the channel region.

### BRIEF DESCRIPTION OF THE DRAWINGS

The present invention will hereinafter be described in conjunction with the following drawing figures, wherein like numerals denote like elements, and wherein:

FIG. 1 is a cross-sectional view of a portion of a dual bit memory device available in the prior art;

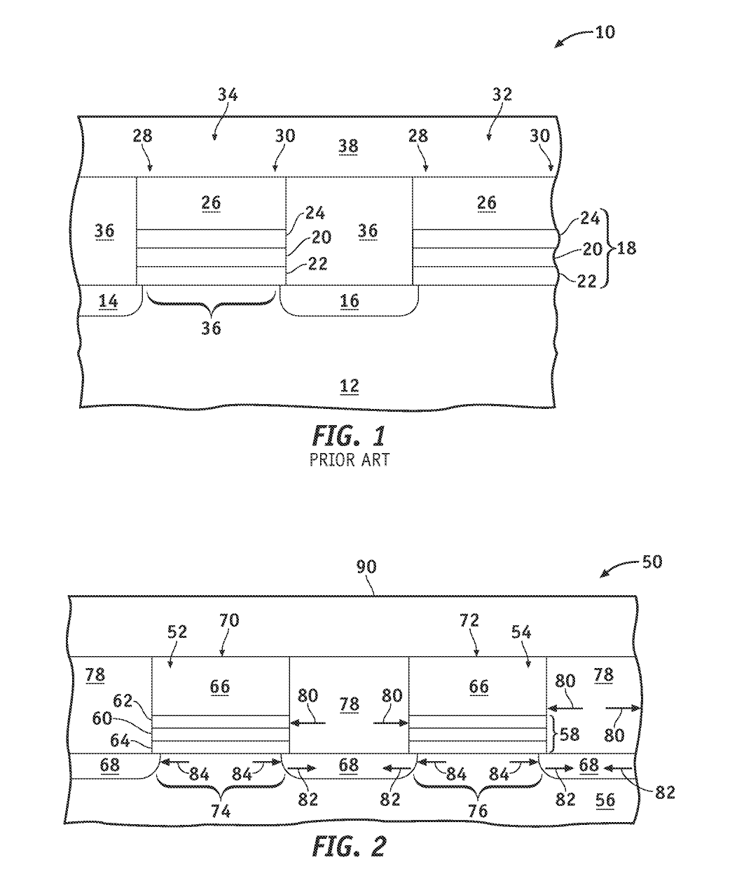

FIG. 2 is a cross-sectional view of a portion of a dual bit memory device in accordance with an exemplary embodiment of the present invention; and

FIGS. 3-7 illustrate a method for fabricating a dual bit memory device in accordance with an exemplary embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

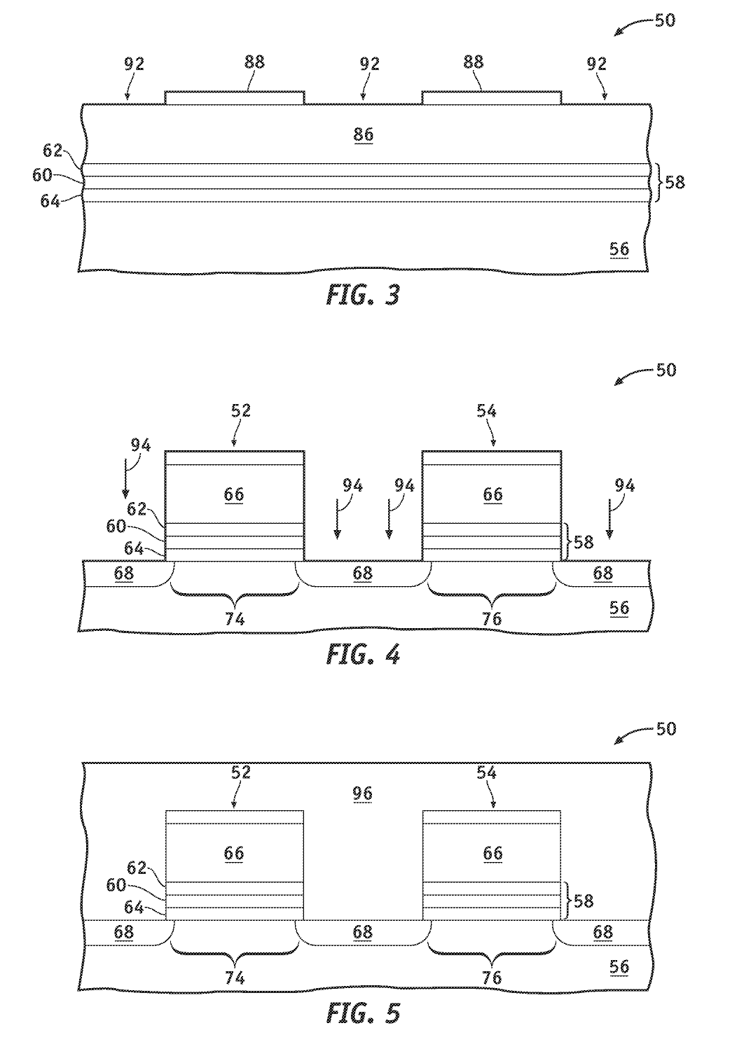

Referring to FIG. 2, in accordance with an exemplary embodiment of the present invention, a portion of a dual bit flash memory device 50 that may be fabricated with enhanced device performance is illustrated. The portion of memory device 50 shown in FIG. 2 is illustrated with two memory cells, a first memory cell 70 and a second memory cell 72. It will be appreciated, however, that memory device 50 may comprise any suitable number of memory cells and, preferably, comprises hundreds or thousands of memory cells. First memory cell 70 has a first gate stack 52 and second memory cell 72 has a second gate stack 54, which gate stacks are both disposed on a P-type silicon substrate 56. Each gate stack 52 and 54 comprises a multi-layer dielectric-charge trapping-dielectric stack 58. Charge trapping stack 58 may comprise a thin first insulating layer 64, a charge trapping layer 60, and a second insulating layer 62. Thin first insulating layer 64 is often referred to as a tunnel oxide layer, a layer through which programming or erasing charge carriers can tunnel. Charge trapping layer 60 can be, for example, a layer of silicon nitride, silicon-rich silicon nitride, polycrystalline silicon, a combination of these, or any of the other well known charge trapping materials. Stoichiometric silicon nitride is SiₓN_{y} for which x=3 and n=4; silicon-rich silicon nitride is a silicon/nitrogen material for which x/y is greater than ¾. Preferably, second insulating layer 62 comprises a silicon oxide. In an exemplary embodiment of the invention, multi-layer stack 58 has a total thickness that is no greater than about 30 nm. A control gate 66 overlies the upper oxide layer 62 of the charge tapping stacks 58 of each stacks 52 and 54. The control gate may be formed of polycrystalline silicon and may be doped with an N-type impurity.

An impurity-doped region 68, otherwise known as a bit line region, is disposed within substrate 56 substantially between first gate stack 52 and second gate stack 54. First memory cell 70 further comprises a first channel region 74 that is disposed in substrate 56 underlying first gate stack 52 and substantially between two bit line regions 68. Similarly, second memory cell 72 further comprises a second channel region 76 that is disposed in substrate 56 underlying second gate stack 54 and substantially between two bit line regions 68.

An intrinsically tensile-stressed insulating member 78 is disposed overlying the bit line regions 68 and between first gate stack 52 and second gate stack 54. The current carrying capability and hence the performance of a memory cell, such as cells 70 and 72, is proportional to the mobility of the majority carrier in the channel of the cell. The mobility of electrons, the majority carrier in a N-channel device, can be increased by imparting a uniaxial lateral tensile stress to the channel. Accordingly, intrinsically tensile-stressed insulating member 78 is fabricated to have a tensile stress, indicated by arrows 80, such that a compressive stress, indicated by arrows 82, is transmitted to the underlying bit line region 68. In turn, the compressive stress of underlying bit line region 68 transmits a uniaxial lateral tensile stress, indicated by arrows 84, to channel regions 74 and 76. This tensile stress causes a lateral stretching or tensile strain of the silicon crystal lattice of the channel regions. This in turn results in an increase in mobility of electrons through the channel regions 74 and 76 and, hence, an increase in speed of the memory cells 70 and 72. In an exemplary embodiment of the invention, the insulating member has an intrinsic tensile stress of at least about 0.5 GPa, preferably at least about 1.5 GPa.

The insulating member 78 may comprise any suitable insulating material, such as, for example, a silicon oxide or a silicon nitride, that has been deposited, treated, or otherwise fabricated to have an intrinsic tensile stress that is greater than a tensile stress that may result as a side effect of conventional oxidation, etch, deposition, or thermal steps. In other words, as used herein, the term “intrinsic tensile stress” means that stress that is intentionally induced in insulating member 78 to cause a tensile stress to be transmitted to channel regions 74 and 76. Memory device 50 further comprises a conductive word line 90 that overlies insulating member 78 and is in electrical communication with gate stacks 52 and 54 of memory cells 70 and 72, respectively.

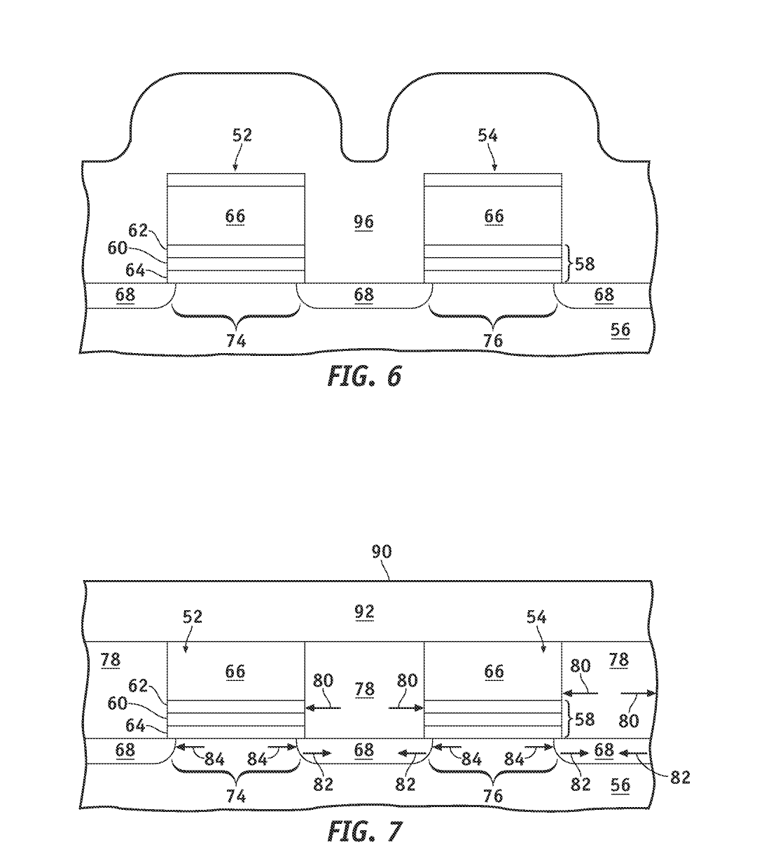

In accordance with an exemplary embodiment of the present invention, FIGS. 3-7 illustrate a method for fabricating a memory device, such as the flash memory device 50 of FIG. 2, that can be scaled with decreased device dimensions while increasing device speed. FIGS. 3-7 illustrate various cross-sectional views of flash memory device 50. Various steps in the manufacture of flash memory device 50 are well known and so, in the interest of brevity, many conventional steps will only be mentioned briefly herein or will be omitted entirely without providing well known process details.

As illustrated in FIG. 3, the manufacture of flash memory device 50 begins with a silicon substrate 56. As used herein, the term “silicon substrate” will be used to encompass the relatively pure silicon materials typically used in the semiconductor industry as well as silicon admixed with other elements such as germanium, carbon, and the like. The term “silicon substrate” also is used to encompass the substrate itself together with metal or insulator layers that may overly the substrate. Silicon substrate 56 may be a bulk silicon wafer or a thin layer of silicon on an insulating layer (commonly known as a silicon-on-insulator wafer or SOI wafer) that, in turn, is supported by a silicon carrier wafer.

A first insulating layer 64, a charge trapping layer 60, and a second insulating layer 62 of a multi-layer dielectric-charge trapping-dielectric stack 58 are formed overlying substrate 56. Preferably insulating layer 64 is a layer of silicon dioxide having a thickness of about 2-10 nanometers (nm), more preferably about 5 nm. Layer 64 can be a thermally grown layer of silicon dioxide or can be deposited, for example, by low pressure chemical vapor deposition (LPCVD). Charge trapping layer 60 can be deposited, for example, to a thickness of about 3 to 20 nm by chemical vapor deposition (CVD), plasma enhanced chemical vapor deposition (PECVD), low pressure chemical vapor deposition (LPCVD), or by atomic layer deposition (ALD). The silicon oxide layers can be deposited, for example, from either a tetraethylorthosilicate (TEOS) or SiH₄ (silane) source or can be grown thermally from silicon oxide, silicon nitride, or silicon-rich silicon nitride. The silicon nitride or silicon-rich silicon nitride can be deposited, for example, from the reaction of dichlorosilane and ammonia.

A control gate material layer 86, preferably of polycrystalline silicon or, in the alternative, metal or other conductive material, is deposited overlying the multi-layer stack 58. The layer of polycrystalline silicon can be deposited as an impurity doped layer, but is preferably deposited as undoped polycrystalline silicon and is subsequently impurity doped by ion implantation. A layer 88 of antireflective coating material (ARC) such as silicon oxide, silicon nitride, or silicon oxynitride can be deposited onto the surface of the polycrystalline silicon layer 86 to aid in subsequently patterning the polycrystalline silicon. The polycrystalline material can be deposited to a thickness of about 300 angstroms to about 1400 angstroms by LPCVD by the hydrogen reduction of silane (SiH₄). ARC layer 88 can be deposited to a thickness of about 50 nm, also by LPCVD. In an exemplary embodiment of the invention, the ARC layer 88 is patterned using conventional photolithography techniques to form an opening 92.

Referring to FIG. 4, the polycrystalline silicon layer 86 and the multi-layer stack 58 are etched to form control gates 66 of a first gate stack 52 and a second gate stack 54. Layer 86 and multi-layer stack 58 can be etched by, for example, plasma etching in a Cl⁻ or HBr/O₂ chemistry. ARC layers 88 and gate stacks 52 and 54 then are used as an ion-implantation mask to form an impurity-doped region or bit line region 68 in silicon substrate 56. The bit line region 68 preferably is formed by implanting an N-type impurity dopant, indicated by arrows 94, which preferably are arsenic ions or phosphorous ions. Upon fabrication of bit line regions 68, channel regions 74 and 76 underlying gate stacks 52 and 54, respectively, are formed. Following the formation of bit line region 68, the ARC layer 88 can be removed using conventional methods.

The method in accordance with an embodiment of the invention continues with the formation of an intrinsically tensile-stressed insulating layer 96. As described above, the insulating layer 96 may comprise any suitable insulating material, such as, for example, a silicon oxide or a silicon nitride, that has been deposited, treated, or otherwise fabricated to have an intrinsic tensile stress that is greater than a tensile stress that may result as a side effect of oxidation, etch, deposition, or thermal steps. In other words, as used herein, the term “intrinsic tensile stress” means that stress that is intentionally induced in insulating layer 96 to cause a compressive stress to be transmitted to channel regions 74 and 76.

It will be appreciated that the level of the tensile stress in layer 96 can be controlled by controlling a number of factors including the relative reactant flow rates, deposition pressure, and temperature of the deposition process. For example, the insulating layer may be a nitride film, preferably including silicon nitride (e.g., SiN, Si_{X}N_{Y}), a silicon oxide film (Si_{X}O_{Y}), or silicon oxynitride film (e.g., Si_{X}O_{Y}N_{Z}), where the stoichiometric proportions x, y, and z may be selected according to CVD process variables as are known in the art to achieve a desired tensile stress in a deposited dielectric layer. In a preferred embodiment of the invention, the insulating member is fabricated to have an intrinsic tensile stress of at least about 0.5 GPa, preferably at least about 1.5 GPa.

As illustrated in FIG. 5, in one exemplary embodiment of the present invention, intrinsically tensile-stressed insulating layer 96 may be formed by depositing a blanket layer of insulating material, such as by PECVD, and then subjecting the deposited layer to plasma treatment or ultra violet thermal processing (UVTP), both treatments of which are well known in the art. As illustrated in FIG. 6, in another exemplary embodiment of the present invention, intrinsically tensile-stressed insulating layer 96 may be conformally deposited by LPCVD process, ALD, or sub-atmospheric CVD (SACVD).

The method in accordance with one embodiment of the invention is continued by the removal of a portion of tensile-stressed insulating layer 96 that overlies the control gates 66 of gate stacks 52 and 54, as illustrated in FIG. 7. In one embodiment of the invention, insulating layer 96 may be subjected to a chemical mechanical planarization (CMP) process to remove portions thereof. In another embodiment of the invention, insulating layer 96 may be etched to expose control gates 66. Upon removal of portions of insulating layer 96 that overlie control gates 66, an intrinsically tensile-stressed insulating member 78 is formed between gate stacks 52 and 54 and overlying bit line region 68. As described above, intrinsically tensile-stressed insulating member 78 has a tensile stress, indicated by arrows 80, such that a compressive stress, indicated by arrows 82, is transmitted to the underlying bit line region 68. In turn, the compressive stress of underlying bit line region 68 transmits a uniaxial lateral tensile stress, indicated by arrows 84, to channel regions 74 and 76. This tensile stress causes a lateral stretching or tensile strain of the silicon crystal lattice of the channel regions, which results in an increase in mobility of electrons through the channel regions 74 and 76 and, hence, an increase in speed of the memory cells 70 and 72.

In another alternative embodiment of the invention, intrinsically tensile-stressed insulating elements 78 can be formed after the removal of portions of the insulating layer. In this regard, a layer of insulating material, such as any of the insulating materials described above for layer 96, is deposited overlying bit line region 68 and gate stacks 52 and 54. Portions of the insulating material layer overlying the control gates 66 are removed and the remaining portions are subjected to a treatment, such as, for example, a plasma or UVTP treatment, that induces the tensile stress in insulating members 78.

The method in accordance with one embodiment of the invention is continued by depositing a blanket layer 92 of polycrystalline silicon or other conductive material in electrical contact with control gates 66 and overlying insulating members 78. The blanket layer is preferably deposited as an impurity doped layer of polycrystalline silicon or can be deposited as a polycrystalline silicon that is subsequently doped by ion implantation. Although not seen in this cross sectional view, blanket layer 92 is photolithographically patterned and etched to form a word line 90 that is electrically coupled to control gates 66 and that is disposed perpendicular to bit line region 68.

Those of skill in the art will appreciate that a completed memory device 50 will include isolation such as shallow trench isolation between devices that need to be electrically isolated, electrical contacts to the bit line regions and to the word lines, bit line drivers, word line drivers, clock circuits, address decoding circuits and/or the like. Fabrication of such structural and circuit elements can be easily integrated with the method for fabricating the memory device structure that has been described herein to fabricate a complete semiconductor memory device.

Accordingly, dual bit memory devices and methods for fabricating dual bit memory devices have been provided. The devices and methods provide for scaled memory devices while enhanced operating speed. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

1. A method for fabricating a memory device, the method comprising the steps of:
fabricating a first gate stack and a second gate stack overlying a P-type silicon substrate;
implanting an impurity dopant into the substrate substantially between the first gate stack and the second gate stack to form an impurity-doped region of the substrate, wherein a first channel region underlies the first gate stack adjacent to the impurity-doped region;
forming an intrinsically tensile-stressed insulating member such that it is between but not overlying the first and the second gate stacks and is overlying the impurity-doped region, wherein the tensile-stressed insulating member causes a uniaxial lateral tensile stress to be transmitted to the first channel region; and
forming a word line overlying the intrinsically tensile-stressed insulating member and in electrical contact with the first gate stack and the second gate stack.

2. The method of claim 1, wherein the step of implanting an impurity dopant comprises the step of implanting an impurity dopant into the substrate substantially between the first gate stack and the second gate stack to form the impurity-doped region of the substrate, wherein a second channel region underlies the second gate stack adjacent to the impurity-doped region.

3. The method of claim 2, wherein the step of forming an intrinsically tensile-stressed insulating member comprises the step of forming the intrinsically tensile-stressed insulating member between the first and the second gate stacks and overlying the impurity-doped region, wherein the tensile-stressed insulating member causes a uniaxial lateral tensile stress to be transmitted to the second channel region.

4. The method of claim 1, wherein the step of forming an intrinsically tensile-stressed insulating member comprises the steps of:
depositing a layer of insulating material overlying the impurity doped region, the first gate stack, and the second gate stack;
subjecting the layer of insulating material to ultra violet thermal processing or plasma processing; and
removing a portion of the layer of insulating material that overlies the first gate stack and the second gate stack.

5. The method of claim 4, wherein the step of removing a portion of the layer of insulating material is performed before the step of subjecting the layer of insulating material to ultra violet thermal processing or plasma processing.

6. The method of claim 1, wherein the step of forming an intrinsically tensile-stressed insulating member comprises the steps of depositing a layer of insulating material overlying the impurity doped region, the first gate stack, and the second gate stack using a deposition reactant flow rate, a deposition pressure, a deposition temperature, or a combination thereof to induce intrinsic tensile stress in the layer of insulating material and removing a portion of the layer of insulating material overlying the first gate stack and the second gate stack.

7. The method of claim 1, wherein the step of forming an intrinsically tensile-stressed insulating member comprises the steps of depositing a layer of insulating material overlying the impurity doped region, the first gate stack, and the second gate stack by low pressure chemical vapor deposition and removing a portion of the layer of insulating material overlying the first gate stack and the second gate stack.

8. The method of claim 1, wherein the step of implanting an impurity dopant into the substrate comprises the step of implanting an N-type impurity dopant into the substrate.

9. The method of claim 1, wherein the step of fabricating a first gate stack and a second gate stack overlying a substrate comprises the steps of:
forming a charge trapping layer overlying the substrate;
depositing a control gate material layer overlying the substrate; and
etching the control gate material layer and the charge trapping layer to expose the silicon substrate.

10. The method of claim 1, wherein the step of forming an intrinsically tensile-stressed insulating member comprises the step of forming an insulating member having an intrinsic tensile stress at least about 0.5 GPa.

11. The method of claim 1, wherein the step of forming an intrinsically tensile-stressed insulating member comprises the step of forming an insulating member having an intrinsic tensile stress at least about 1.5 GPa.

12. A method for enhancing the speed of a dual bit memory device, the method comprising the steps of:
forming a charge trapping layer overlying a P-type silicon substrate;
depositing a control gate material layer overlying the charge trapping layer;
etching the control gate material layer and the charge trapping layer to form a first gate stack and a second gate stack;
forming an impurity-doped region in the substrate substantially between the first gate stack and the second gate stack; and
fabricating an intrinsically tensile-stressed insulating member such that it is between but not overlying the first and the second gate stacks and is overlying the impurity-doped region, wherein the intrinsically tensile-stressed insulating member has an intrinsic tensile stress of at least about 0.5 GPa.

13. The method of claim 12, wherein the step of fabricating an intrinsically tensile-stressed insulating member comprises the steps of:
depositing a layer of insulating material overlying the impurity doped region, the first gate stack, and the second gate stack;
subjecting the layer of insulating material to ultra violet thermal processing or plasma processing; and
removing a portion of the layer of insulating material that overlies the first gate stack and the second gate stack.

14. The method of claim 12, wherein the step of fabricating an intrinsically tensile-stressed insulating member comprises the steps of depositing a layer of insulating material overlying the impurity doped region, the first gate stack, and the second gate stack by low pressure chemical vapor deposition and removing a portion of the layer of insulating material overlying the first gate stack and the second gate stack.

15. The method of claim 12, wherein the step of fabricating an intrinsically tensile-stressed insulating member comprises the step of forming an insulating member having an intrinsic tensile stress at least about 1.5 GPa.

16. The method of claim 12, wherein the step of forming an impurity-doped region in the substrate comprises the step of forming an N-type impurity-doped region into the substrate.

17. A memory device comprising:
a P-type silicon substrate;
a dielectric-charge trapping-dielectric stack disposed on the substrate;
an N⁺-doped impurity region disposed within the substrate;
a channel region disposed within the substrate underlying the dielectric-charge trapping-dielectric stack;
an intrinsically tensile-stressed insulating member disposed overlying the N⁺-doped impurity region, wherein the tensile-stressed insulating member is configured to cause a uniaxial lateral tensile stress to be transmitted to the channel region.

18. The memory device of claim 17, wherein the intrinsically tensile-stressed insulating member has an intrinsic tensile stress at least about 0.5 GPa.

19. The memory device of claim 19, wherein the intrinsically tensile-stressed insulating member has an intrinsic tensile stress at least about 1.5 GPa.

20. The memory device of claim 17, wherein the dielectric-charge trapping-dielectric stack comprises a first silicon oxide layer, a silicon-rich silicon nitride charge trapping layer overlying the first silicon oxide layer, and a second silicon oxide layer overlying the silicon-rich silicon nitride charge trapping layer.
